(19) United States
(12) Patent Application Publication
(10) Pub. No.: US 2018/0294627 A1
(43) Pub. Date: Oct. 11, 2018

(54) CABLE FIXATION ELEMENT IN LOW VOLTAGE COMPARTMENTS

(71) Applicant: ABB SCHWEIZ AG, Baden (CH)

(72) Inventor: Robby Zitzmann, Erkrath (DE)

(21) Appl. No.: 16/009,223

(22) Filed: Jun. 15, 2018

Related U.S. Application Data
(63) Continuation of application No. PCT/EP2016/081071, filed on Dec. 14, 2016.

(30) Foreign Application Priority Data
Dec. 16, 2015 (EP) 15200555.9

(51) Int. Cl. H02B 1/20; H02G 3/32; H02B 1/015

(52) U.S. Cl. CPC H02B 1/202; H05K 7/18; H02B 1/015; H02G 3/32

(57) ABSTRACT

A cable fixation element for low voltage compartments includes an openable ring element, through which a number of cables can be aligned in parallel, the cable fixation element having a fixing unit by which the cable fixation element can be fixed on a cable mounting board. The ring is openable such that a physical opening direction is parallel to a long axis of the cables, which have to be placed in the cable fixation element. A frame structure of the cable fixation element is provided at all sides of the frame in double layer, except of the top side, where c-structured portions are implemented.

### CROSS-REFERENCE TO PRIOR APPLICATION

This application is a continuation of International Patent Application No. PCT/EP2016/081071, filed on Dec. 14, 2016, which claims priority to European Patent Application No. EP 15200555.9, filed on Dec. 16, 2015. The entire disclosure of both applications is hereby incorporated by reference herein.

### FIELD

The invention relates to a cable fixation element in low voltage compartments with an openable ring element, through which a number of cables can be aligned in parallel, wherein the cable fixation element has means, by which the cable fixation element can be fixed on a cable mounting board.

### BACKGROUND

In low voltage compartments, a high amount of cables needed to be lead and handled. For realizing this, content cable holders are state of the art.

Usually cable holder are built up like closed rings or openable rings, or u-shaped. U-shaped cable holder or fixation elements cannot really fix the position of cables or cable harnesses.

The well known closed ring is stiff but the disadvantage is, that the cables must be pulled through the hole. This results unfortunately in additional time of mounting and installation of the cables, or the complete wiring.

U-shaped cable holders can be equipped fast with cables, but due to that, they are an open profile, and they are not as stiff enough, like closed cable holders. Therefore they cannot be equipped with the same amount of wires than the closed cable holders.

To overcome that problem, systems are known, which are open and can be closed later. The opening direction is oriented perpendicular to the cables along axis orientation. The disadvantages of these systems are, that they are based on two parts, or that the user have to close them by the need of two hands and usually the access to the position, where the cable holders are placed, is not as good for that. Furthermore, an opening direction perpendicular to the long axis of the wiring, needs additional space, which finally reduces the available cross-section of the cable holder, and with that the possible number of cables is reduced.

### SUMMARY

In an embodiment, the present invention provides a cable fixation element for low voltage compartments, the cable fixation element comprising: an openable ring element, through which a number of cables can be aligned in parallel, the cable fixation element having a fixing unit by which the cable fixation element is configured to be fixed on a cable mounting board, wherein the ring is openable such that a physical opening direction is parallel to a long axis of the cables, which have to be placed in the cable fixation element, and wherein a frame structure of the cable fixation element is provided at all sides of the frame in double layer, except of the top side, where c-structured portions are implemented.

### BRIEF DESCRIPTION OF THE DRAWINGS

The present invention will be described in even greater detail below based on the exemplary figures. The invention is not limited to the exemplary embodiments. Other features and advantages of various embodiments of the present invention will become apparent by reading the following detailed description with reference to the attached drawings which illustrate the following:

FIG. 1: Perspective view of the cable fixation element

FIG. 2: Installation of the cable fixation element in a switchboard

### DETAILED DESCRIPTION

In an embodiment, the present invention provides a ring that is openable such that the physical opening direction is parallel to the long axis of the cables, which have to be placed in the fixation element, and additionally, that the frame structure of the cable fixation element is provided at all sides of the frame in double layer, except of the top side, where the c-structured portions are implemented.

For such a cable fixation element in low voltage compartments with an openable ring element, through which a number of cables can be aligned in parallel, wherein the cable fixation element has means, by which the cable fixation element can be fixed on a cable mounting board, the invention is, that the ring is openable in that way, that the physical opening direction is parallel to the long axis of the cables, which have to be placed in the fixation element.

With the additional, that the frame structure of the cable fixation element is provided at all sides of the frame in double layer, except of the top side, where the c-structued portions are implemented, the cable fixation element is stiffened in the cable enclosing structure, except of the side, where the c-structured portions are implemented, in order to realize a easier opening and closing.

So the double-layered structure is located, where it is needed for realizing optimal mechanical fixation forces, to carry the weight of the cables, but not to hinder an easy opening or closing.

The basical feature of the application is, that the opening direction of the cable fixation element in function of a cable holder, is in line with the cables, from the side. As there is no movement to the top when opening the cable fixation element, no space is required here for opening and the complete space can be used for the cables.

In a further advantageous embodiment, the ends of the openable ring are provided with complementarily formed c-structured portions, like hooks, which interlocks in the closed position of the fixation element, and can be opened by a sidewarded relative contrary side movement in a remove direction, and can be closed by a movement in succession to another, wherein sidewarded means parallel to the cable long axis, but perpendicular to the ring profile of the cable fixation element.

So these c-structured portions can be interpretated as closing noses of the cable fixation element and are designed in that way, that the force created by the cables in closed direction enforces the closing but can be opened for all that easily with two fingers during installation or maintanance. This is realized by the special arrangement of the designed bevels in the nose area.

A further embodiment of the invention is, that the cable fixation element has a fixing nose for an intended twist protection, which ensures that the cable fixation element can be assembled in one direction only, which ensures that the opening is on the right position for installation and maintenance.

As the fixing point and the integrated twist protection are different in size, in addition this guarantees a unique installation direction to avoid wrong installation in subassemblies.

In a further advantageous embodiment of the invention, the cable fixation element has a further integrated fixing element, which is additionally applicable for fixing the head profile for low voltage-components too.

In a further advantageous embodiment of the invention, the cable fixation element additionally is provided with an opening, extended through the double layered structure, in order to be fixed to a complementary peg or pin, fixed on the switchboard.

In a further embodiment, the cable fixation element can be used for sideward application, if the space or the border conditions demand this orientation.

In a further advantageous embodiment, the cable fixation element including all aforesaid portions, fixing element, fixing nose and c-structured portions are formed as a one-piece element, so that all aforesaid parts and portions are integrally formed at the cable fixation element.

In a very important embodiment of the invention, the frame structure of the cable fixation element is realized at all sides of the frame in interconnected double layers, except of the top side, where the c-structured portions are implemented.

This results first in an high flexibility, but secondly also in a prevention of a break

In a final advantageous embodiment, the cable fixation element is realized as injection or cast moulded element.

With that, the fixation element is easy in production with constant quality.

The fixing of the cable fixation element is used for fixing the head profile to. Because of that, a separate fixing of the head profile is not necessary anymore. This saves fixing material and assembling time.

The wires can be applicated faster also in areas where the space and the access is constricted. Therefore the assembling time during production and during service is less.

More wires can be applicated in the same space. The cable fixation element can be assembled in only one defined direction which ensures that later the cable fixation element is positioned correct for placing in the wires for production or later for service.

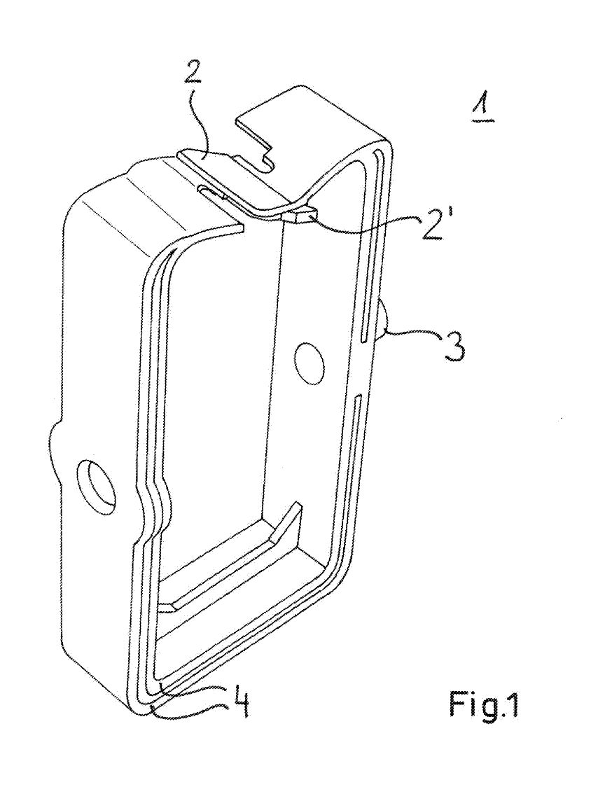

FIG. 1 shows a perspective side view of the invention related cable fixation element. Like it is visible, the sides of the openable o-ring shaped form of the cable fixation element are provided with interconnected double layers. The top of the cable fixation element is provided with the c-shaped portions, like complementary hooks. It is clear, that in order to open or to close the cable fixation element the element as such has to be moved or bended at the top portion in a direction parallel to the cable alignment through the o-ring shaped cable fixation element. The displayed position of the c-structured portions is opened. For closing, these portions has to be moved into a position, that the c-shaped portions grip or snatch into one another.

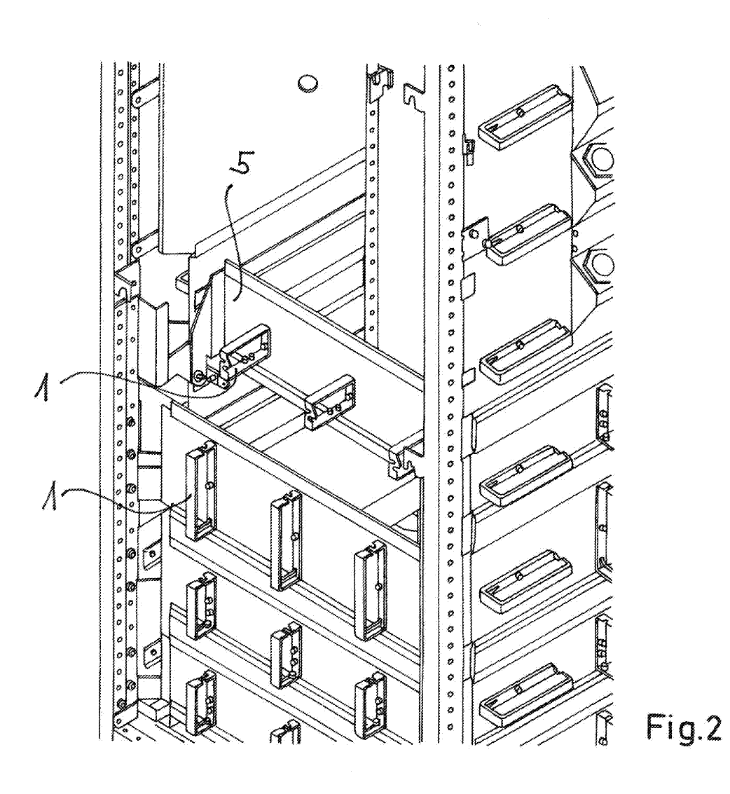

FIG. 2 shows the possible arrangements of the cable fixation elements in a switchboard. Fixation noses are integrally formed at one small side as well as on at least one long side of the cable fixation element, in such, that they can be fastend to the switchboard for a flat cable arrangement close to the fixation sheet of the switchboard, or flat in a kind of a lying arrangement of a cable harness.

Furthermore, the integrated fixation nose at the cable fixation element allows to rotate the orientation, in order to follow the intended cable alignment also, in changing the angle of installation.

So, the invention is a new cable fixation element, which can be handled, that means opened and closed, by the use of two fingers only. The open situation gave the installation worker the chance to bring in or take out the cables as fast as possible. The closed situation fix the cables and make the application more stiff and stable.

The fixation element is constructed in its closed position, like a closed O-ring. On the top the beam is opened. The two opened ends of the beam are designed like two C-structured complementary portions, like hooks with a c-shape, which can be closed by twisting them with two fingers.

The two c-shaped portions or hooks are designed in that way, that if they are closed and filled with wires the weight of the wires reinforce the closing situation. Also if the wires are reinforcing the closing situation the cable fixation element can be opened easily with two fingers due to the design of the hooks to be filled with more wires if necessary.

The open direction of the wires results in the fact that more wires can be placed into the cable fixation element.

A twist protection ensures the correct assembly.

The design of the fixing of the cable fixation element make it possible to fix the head profile for secondary equipment in one step.

While the invention has been illustrated and described in detail in the drawings and foregoing description, such illustration and description are to be considered illustrative or exemplary and not restrictive. It will be understood that changes and modifications may be made by those of ordinary skill within the scope of the following claims. In particular, the present invention covers further embodiments with any combination of features from different embodiments described above and below. Additionally, statements made herein characterizing the invention refer to an embodiment of the invention and not necessarily all embodiments.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

### NUMBERING

1 cable fixation element
2 c-shaped portions, complementary hooks
2′ c-shaped portions, complementary hooks
3 fixing nose, fixing element
4 double layered structure
5 switchboard

What is claimed is:

1. A cable fixation element for low voltage compartments, the cable fixation element comprising:
an openable ring element, through which a number of cables can be aligned in parallel, the cable fixation element having a fixing unit by which the cable fixation element is configured to be fixed on a cable mounting board,
wherein the ring is openable such that a physical opening direction is parallel to a long axis of the cables, which have to be placed in the cable fixation element, and
wherein a frame structure of the cable fixation element is provided at all sides of the frame in double layer, except of the top side, where c-structured portions are implemented.

2. The cable fixation element according to claim 1, wherein ends of the openable ring are provided with complementarily formed C-structured portions, which are configured to interlock in a closed position of the cable fixation element, are configured to be opened by a sidewarded relative contrary side movement in a remove direction, and are configured to be closed by a movement in succession to another, and
wherein sidewarded means parallel to the long axis of the cables, but perpendicular to a ring profile of the cable fixation element.

3. The cable fixation element according to claim 1, further comprising a fixing nose for configured for twist protection, which ensures that the cable fixation element can be assembled in one direction only, which ensures that the opening is on a right position for installation and maintenance.

4. The cable fixation element according to claim 1, further comprising a further integrated fixing element configured for fixing a head profile of low voltage-components.

5. The cable fixation element according to claim 1, further comprising an opening, extended through the double layered structure, in order to be fixed to a complementary peg or pin, fixed on the switchboard.

6. The cable fixation element according to claim 3, wherein the fixing element, fixing nose, and c-structured portions comprise a one-piece element, so that all such parts and portions are integrally formed at the cable fixation element.

7. The cable fixation element according to claim 1, wherein the cable fixation element comprises an injection or cast moulded element.
